(19) United States
(12) Patent Application Publication
(10) Pub. No.: US 2025/0268005 A1
(43) Pub. Date: Aug. 21, 2025

(54) DISPLAY DEVICE AND METHOD FOR MANUFACTURING DISPLAY DEVICE

(71) Applicant: Samsung Display Co., LTD., Yongin-si (KR)

(72) Inventors: Tae Gyun KIM, Yongin-si (KR); Ki Bum KIM, Yongin-si (KR); So Young LEE, Yongin-si (KR)

(73) Assignee: Samsung Display Co., LTD., Yongin-si (KR)

(21) Appl. No.: 19/050,616

(22) Filed: Feb. 11, 2025

(30) Foreign Application Priority Data
Feb. 15, 2024 (KR) 10-2024-0021586

(51) Int. Cl. H10H 29/49; H10H 29/01

(52) U.S. Cl. CPC H10H 29/49; H10H 29/012

(57) ABSTRACT

A display device comprises a display area and a non-display area, a substrate including a plurality of pixel electrodes disposed in the display area, a light emitting element disposed on each of the plurality of pixel electrodes and including a first semiconductor layer, an active layer, and a second semiconductor layer, a first common connection electrode and a second common connection electrode disposed in the non-display area and a bonding electrode disposed between the light emitting element and the plurality of pixel electrodes, wherein the second common connection electrode has a thickness thinner than the bonding electrode.

### CROSS-REFERENCE TO RELATED APPLICATION

This application claims priority to and benefits of Korean Patent Application No. 10-2024-0021586 under 35 U.S.C. § 119, filed on Feb. 15, 2024, in the Korean Intellectual Property Office (KIPO), the contents of which are incorporated herein by reference.

### BACKGROUND

### 1. Technical Field

The disclosure relates to a display device and a method for manufacturing the same.

### 2. Description of the Related Art

The importance of display devices is gradually increasing along with the development of multimedia. In response to this, various display devices such as liquid crystal display devices and light emitting display devices are being developed. Among these, light emitting display device includes a display panel including light emitting elements, and is applied to various types of electronic devices, including portable electronic devices and televisions, as well as virtual reality (VR) devices and augmented reality (AR) devices.

### SUMMARY

Aspects and features of embodiments of the disclosure are to provide a method of manufacturing a display device that may increase the manufacturing efficiency of a display panel including light emitting elements.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment, display device comprises a display area and a non-display area, a substrate including a plurality of pixel electrodes disposed in the display area, a light emitting element disposed on each of the plurality of pixel electrodes and including a first semiconductor layer, an active layer, and a second semiconductor layer, a first common connection electrode and a second common connection electrode disposed in the non-display area and a bonding electrode disposed between the light emitting element and the plurality of pixel electrodes, wherein the second common connection electrode has a thickness thinner than the bonding electrode.

In embodiment, the second common connection electrode and the bonding electrode may be disposed on a same layer, and the first common connection electrode and the plurality of pixel electrodes may be disposed on a same layer.

In embodiment, the second common connection electrode and the bonding electrode may include a same material.

In embodiment, the first common connection electrode and the plurality of pixel electrodes may have a same thickness.

In embodiment, the first common connection electrode and the plurality of pixel electrodes may include a same material.

In embodiment, the bonding electrode may have a size and shape corresponding to the plurality of pixel electrodes.

In embodiment, the bonding electrode may include a first bonding electrode and a second bonding electrode disposed on the first bonding electrode, and the second bonding electrode may have a size and shape corresponding to the first bonding electrode.

In embodiment, the display device may further comprise a common electrode disposed on the light emitting element and electrically connected to the second common connection electrode.

In embodiment, the display device may further comprise a third common connection electrode disposed between the second common connection electrode and the common electrode.

In embodiment, the display device may further comprise a lens-type optical structure disposed on a light emitting element layer including the light emitting elements and the common electrode.

According to an embodiment, a method of manufacturing display device comprises manufacturing an epitaxial wafer including an epitaxial thin film, dividing the epitaxial thin film into epitaxial dies with a size corresponding to an area of each cell area of a backplane substrate including the cell areas, forming a protective layer surrounding the epitaxial dies and planarizing the epitaxial dies, forming a first conductive bonding layer on the epitaxial dies and the protective layer of the epitaxial wafer, forming a second conductive bonding layer on a backplane substrate, disposing the wafer substrate on the backplane substrate so that the epitaxial dies overlap each display area of the backplane substrate, and bonding the first conductive bonding layer and the second conductive bonding layer, removing the wafer substrate from the epitaxial dies, and etching the epitaxial dies to form each light emitting element in light emitting areas included in each cell area.

In embodiment, the forming the protective layer surrounding the epitaxial dies and planarizing the epitaxial dies may include, filling a gap between the epitaxial dies, applying a filler on the wafer substrate to cover the epitaxial dies, and planarizing a top surface of the wafer substrate to expose a top of the epitaxial dies.

In embodiment, the backplane substrate may include pixel electrodes individually provided in light emitting areas of a display area, a first common connection electrode in a non-display area, and an insulating layer filling a space between the pixel electrodes and the first common connection electrode.

In embodiment, the etching of the epitaxial dies to form each light emitting element in the light emitting areas included in each cell area, may include forming each of the light emitting elements on the pixel electrodes.

In embodiment, in the etching of the epitaxial dies to form each light emitting element in the light emitting areas included in each cell area, may include etching a bonded first conductive bonding layer and the second conductive bonding layer to form a bonding electrode between the light emitting element and the pixel electrodes and a second common connection electrode on the first common connection electrode in a same layer.

In embodiment, in the etching of the epitaxial dies to form each light emitting element in the light emitting areas included in each cell area, a thickness of the second common connection electrode of a non-display area may be thinner than a thickness of the bonding electrode of the display area according to a difference in etch rate between the epitaxial die and the protective layer.

In embodiment, in the bonding of the first conductive bonding layer and the second conductive bonding layer, may include the bonding the epitaxial dies to the backplane substrate by a thermal compression (TC) bonding method.

In embodiment, the method may further comprise forming a common electrode on the light emitting elements in each cell area, wherein the common electrode may be electrically connected to the second common connection electrode.

In embodiment, the method may further comprise forming a lens-type optical structure on a light emitting element layer including the light emitting elements and the common electrode.

In embodiment, the method may further comprise separating each cell corresponding to the cell areas into individual display panels by cutting the backplane substrate based on a panel area including the cell areas.

According to the method of manufacturing a display device according to embodiments, before bonding the wafer substrate and the backplane substrate, it is possible to prevent cracking of the epitaxial thin film that may occur during bonding by dividing the epitaxial thin film into sizes corresponding to the cell area and forming a protective layer to protect the epitaxial thin film. Accordingly, the manufacturing efficiency of a display panel including light emitting elements and a display device including the same may be increased, and the yield may be improved.

However, the effects of the disclosure are not limited to the aforementioned effects, and various other effects are included in the specification.

### BRIEF DESCRIPTION OF THE DRAWINGS

FIG. 1 is a schematic perspective view illustrating a display device according to an embodiment.

FIG. 2 is a schematic plan view illustrating an embodiment of area A of FIG. 1.

FIG. 3 is a schematic cross-sectional view illustrating an embodiment of a cross-section of the display panel corresponding to the lines X1-X1′ in FIG. 2.

FIG. 4 is a schematic cross-sectional view illustrating a light emitting element according to an embodiment.

FIG. 5 is a schematic flowchart illustrating a manufacturing method of a display device according to an embodiment.

FIGS. 6 to 22 are schematic diagrams to illustrate a method of manufacturing a display panel according to an embodiment.

FIGS. 23 to 26 are schematic drawings to illustrate a method of manufacturing a display panel according to another embodiment.

FIG. 27 is an example diagram schematically showing a virtual reality device including a display device according to an embodiment.

FIG. 28 is an example diagram schematically showing a smart device including a display device according to an embodiment.

FIG. 29 is a diagram of an example schematically showing a vehicle including a display device according to an embodiment.

FIG. 30 is a diagram of an example schematically showing a transparent display device including a display device according to an embodiment.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

Further, the phrase “in a plan view” means when an object portion is viewed from above, and the phrase “in a schematic cross-sectional view” means when a schematic cross-section taken by vertically cutting an object portion is viewed from the side. The terms “overlap” and “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied herein, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, specific embodiments will be described with reference to the accompanying drawings.

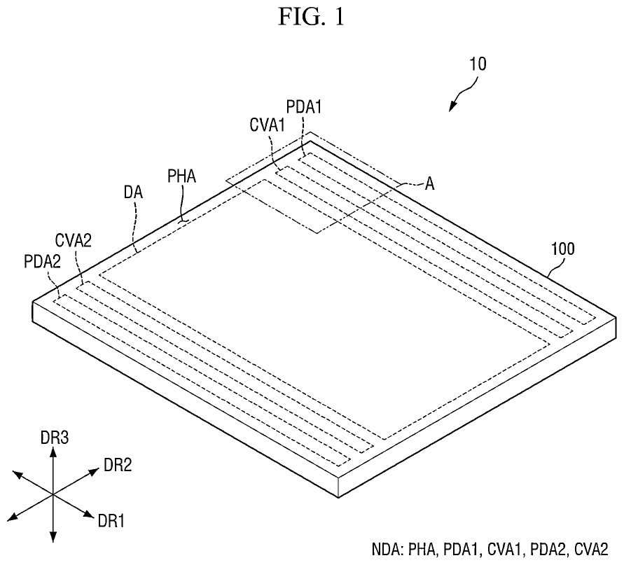

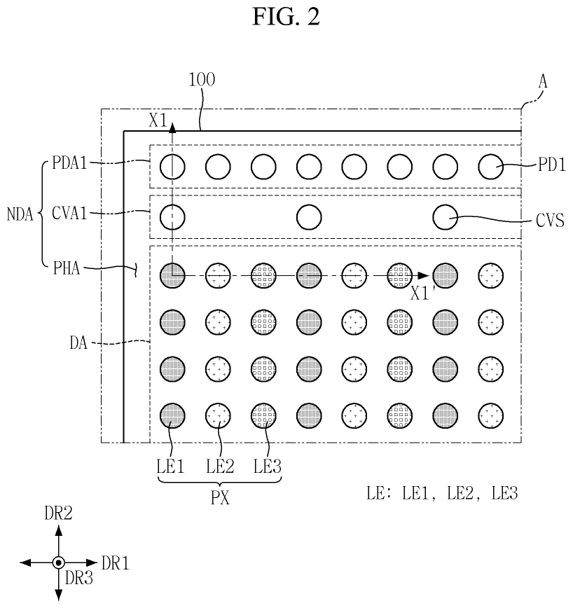

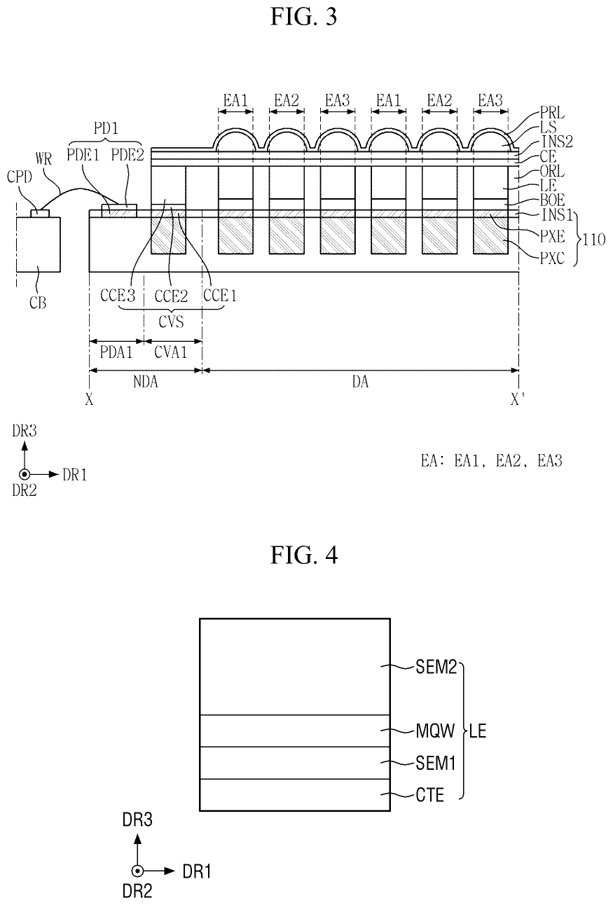

FIG. 1 is a schematic perspective view illustrating a display device according to an embodiment. FIG. 2 is a schematic plan view illustrating an embodiment of area A of FIG. 1. FIG. 3 is a schematic cross-sectional view illustrating an embodiment of a cross-section of the display panel corresponding to the lines X1-X1′ in FIG. 2.

FIGS. 1 to 3 illustrate an embodiment in which the display device 10 is an LEDOS (Light Emitting Diode on Silicon) in which light emitting diodes are disposed as light emitting elements LE on a semiconductor circuit board formed by a semiconductor process using a silicon wafer (e.g., a backplane substrate 110 of a display panel 100 on which a pixel circuit (PXC) or the like is formed based on a silicon wafer). However, devices including light emitting elements LE according to embodiments are not limited thereto. For example, the light emitting elements LE manufactured according to embodiments may be applied to display devices of different types and/or structures or may be applied to devices of different types and/or structures, such as lighting devices, etc.

In FIGS. 1 to 3, the first direction DR1 may indicate a horizontal direction of the display panel 100, and the second direction DR2 may indicate a vertical direction of the display panel 100. The third direction DR3 may indicate a thickness direction of the display panel 100.

First, referring to FIGS. 1 and 2, the display device 10 according to an embodiment may include a display panel 100 including a display area DA and a non-display area NDA.

The display panel 100 may have a rectangular planar shape with a long side in the first direction DR1 and a short side in the second direction DR2. However, the planar shape of the display panel 100 is not limited to this, and the display panel 100 may have other shapes. For example, the display panel 100 may have any other polygonal, circular, elliptical, or non-rectangular planar shapes other than a rectangular shape.

The display area DA may be an area where an image is displayed, and the non-display area NDA may be an area where the image is not displayed. In an embodiment, the planar shape of the display area DA may follow the planar shape of the display panel 100. In FIG. 1, the planar shape of the display area DA is illustrated as a rectangle. The display area DA may be disposed in the central area of the display panel 100. The non-display area NDA may be disposed around the display area DA. In an example, the non-display area NDA may surround the display area DA.

The display area DA may include pixels PX. Each pixel PX may include at least two light emitting elements LE.

In an embodiment, each pixel PX may include three light emitting elements LE. For example, each pixel PX may include a first light emitting element LE1, a second light emitting element LE2, and a light emitting element LE3. The number and/or type of light emitting elements LE provided to the pixels PX may be varied in different embodiments.

In an embodiment, each pixel PX may include light emitting elements LE that emit light of different colors. For example, the first light emitting element LE1, the second light emitting element LE2, and the third light emitting element LE3 may emit light of different colors.

The first light emitting element LE1 may emit first light. The first light may be red light. For example, the main peak wavelength (R-peak) of the first light may be located in a range of about 600 nm to about 750 nm, but embodiments are not limited thereto.

The second light emitting element LE2 may emit second light. The second light may be green light. For example, the main peak wavelength (G-peak) of the second light may be located in a range of about 480 nm to about 560 nm, but embodiments are not limited thereto.

The third light emitting element LE3 may emit third light. The third light may be blue light. For example, the main peak wavelength (B-peak) of the third light may be located in a range of about 370 nm to about 460 nm, but embodiments are not limited thereto.

In another embodiment, the first light emitting element LE1, the second light emitting element LE2, and the third light emitting element LE3 may emit light of the same color as each other. A light conversion layer including a light conversion element (e.g., a quantum dot) for converting the color of light (or a wavelength band corresponding thereto) emitted from the at least one light emitting element LE into light of another color (or a wavelength band corresponding thereto) may be disposed on at least one light emitting element LE among the first light emitting element LE1, the second light emitting element LE2, and the third light emitting element LE3.

In an embodiment, the first light emitting element LE1, the second light emitting element LE2, and the third light emitting element LE3 of each pixel PX may be sequentially disposed in the first direction DR1. In an embodiment, the first light emitting elements LE1 may be arranged in the second direction DR2. The second light emitting elements LE2 may be arranged in the second direction DR2. The third light emitting elements LE3 may be arranged in the second direction DR2. For example, in each pixel column extending in the second direction DR2, the first light emitting element LE1, the second light emitting element LE2, or the third light emitting element LE3 may be arranged. The pixels PX, and the arrangement structure of the light emitting elements LE provided in the pixels PX may be varied in different embodiments.

In an embodiment, the light emitting elements LE may be arranged in the display area DA at substantially equal intervals, but are not limited thereto. For example, the positions and/or array spacing of the light emitting elements LE may be varied depending on the embodiments.

In an embodiment, the sizes (e.g., areas) of the light emitting elements LE may be substantially the same as each other. For example, the first light emitting element LE1, the second light emitting element LE2, and the third light emitting element LE3 may have substantially the same size. However, the embodiments are not limited to this, and the size of each light emitting element LE and/or the area of light emitting areas corresponding to the light emitting elements LE may be varied in different embodiments.

In an embodiment, the light emitting elements LE may have a circular planar shape, but the embodiments are not limited thereto. For example, the light emitting elements LE may have a rectangular shape or another polygonal shape, an elliptical shape, or any other polygonal, elliptical, or irregular shape. Further, the light emitting elements LE may have substantially the same planar shape as each other or may have different planar shapes for each group.

The non-display area NDA may include a first common voltage supply area CVA1, a second common voltage supply area CVA2, a first pad area PDA1, a second pad area PDA2, and a peripheral area PHA.

The first common voltage supply area CVA1 may be disposed between the first pad area PDA1 and the display area DA. The second common voltage supply area CVA2 may be disposed between the second pad area PDA2 and the display area DA. Each of the first common voltage supply area CVA1 and the second common voltage supply area CVA2 may include common electrode connecting portions CVS connected to a common electrode (e.g., common electrode CE in FIG. 3). For example, the common electrode may extend from the display area DA to the first common voltage supply area CVA1 and the second common voltage supply area CVA2 and may be electrically connected to the common electrode connecting portions CVS. A common voltage may be supplied to the common electrode through the common electrode connecting portions CVS.

The common electrode connecting portions CVS may be disposed in a common voltage supply area (e.g., the first common voltage supply area CVA1 and/or the second common voltage supply area CVA2) of the non-display area NDA. The common electrode connecting portions CVS may include a conductive material (e.g., a metal material such as aluminum (Al)). While FIGS. 1 and 2 illustrate the display device 10 in which the common electrode connecting portions CVS are disposed in the non-display area NDA, but the embodiments are not limited thereto. For example, the common electrode connecting portions CVS may be disposed in the display area DA. In an example, the common electrode connecting portions CVS may be disposed in pixel areas or between pixel areas.

The common electrode connecting portions CVS of the first common voltage supply area CVA1 may be electrically connected to at least one of first pads PD1 of the first pad area PDA1. For example, the common electrode connecting portions CVS of the first common voltage supply area CVA1 may be supplied with a common voltage from one of the first pads PD1 of the first pad area PDA1.

The first pads PD1 may be disposed in the first pad area PDA1. The first pads PD1 may be electrically connected to a circuit board CB through a conductive connection member. For example, the first pads PD1 may be electrically connected to a circuit pad provided on a circuit board through wires.

The common electrode connecting portions CVS of the second common voltage supply area CVA2 may be electrically connected to at least one of second pads of the second pad area PDA2. For example, the common electrode connecting portions CVS of the second common voltage supply area CVA2 may be supplied with a common voltage from at least one of the second pads of the second pad area PDA2. In an embodiment, the display panel 100 may not include the second common voltage supply area CVA2.

The first pad area PDA1 may be disposed on a side (e.g., the upper side) of the display panel 100. The first pad area PDA1 may include first pads PD1 connected to an external circuit board.

The second pad area PDA2 may be disposed on another side (e.g., the lower side) of the display panel 100. The second pad area PDA2 may include second pads connected to an external circuit board. In an embodiment, the display panel 100 may not include the second pad area PDA2.

The second pads may be disposed in the second pad area PDA2 of the non-display area NDA. The second pads may be connected to the circuit board through a conductive connection member. For example, the second pads may be electrically connected to circuit pads provided on the circuit board through wires.

The peripheral area PHA may be part of the non-display area NDA excluding the first common voltage supply area CVA1, the second common voltage supply area CVA2, the first pad area PDA1, and the second pad area PDA2. The peripheral area PHA may surround the display area DA, as well as the first common voltage supply area CVA1, the second common voltage supply area CVA2, the first pad area PDA1, and the second pad area PDA2.

Referring to FIG. 3, the display panel 100 may include a backplane substrate 110 and a light emitting element layer 120. In an embodiment, the display panel 100 may further include an optical structure (or light emitting structure) provided on the light emitting element layer 120, for example, a lens-type optical structure LS.

The display panel 100 may further include additional components according to embodiments. For example, the display panel 100 may further include a light conversion layer for converting the color and/or wavelength of light emitted from at least some of the light emitting elements LE, and/or a color filter layer for controlling that light of a particular color is emitted from each of light emitting areas EA.

The display panel 100 may include light emitting areas EA located in the display area DA. Each of the light emitting areas EA may include at least one light emitting element LE. For example, the light emitting areas EA may include a first light emitting area EA1 provided with at least one first light emitting element LE1, a second light emitting area EA2 provided with at least one second light emitting element LE2, and a third light emitting area EA3 provided with at least one third light emitting element LE3. In an embodiment, first light, second light, and third light may be emitted from the first light emitting area EA1, the second light emitting area EA2, and the third light emitting area EA3, respectively.

The backplane substrate 110 may include a display area DA including light emitting areas EA. In an embodiment, the backplane substrate 110 may be a semiconductor circuit board formed through a semiconductor process using a silicon wafer. For example, a silicon wafer may be used as a base member to form the display panel 100.

The backplane substrate 110 may include pixel circuits PXC and pixel electrodes PXE provided in the display area DA. For example, at least one light emitting element LE may be provided in each light emitting area EA of the display panel 100, and the backplane substrate 110 may include pixel circuits PXC and pixel electrodes PXE connected (e.g., electrically connected) to each of the light emitting elements LE disposed in the respective light emitting areas EA.

In an embodiment, the backplane substrate 110 may further include a first insulating layer INS1 disposed around the pixel electrodes PXE.

The pixel circuits PXC may be provided in the display area DA corresponding to the area where each pixel PX and/or the light emitting areas EA are formed. In an embodiment, each of the pixel circuits PXC may include a complementary metal-oxide semiconductor (CMOS) circuit formed using a semiconductor process.

Each of the pixel circuits PXC may include at least one transistor formed through a semiconductor process. Each of the pixel circuits PXC may further include at least one capacitor formed through a semiconductor process.

The pixel circuits PXC may be electrically connected to each pixel electrode PXE. For example, the pixel circuits PXC and the pixel electrodes PXE may be connected in a one-to-one correspondence. Each of the pixel circuits PXC may apply a pixel voltage to the pixel electrode PXE connected thereto.

The pixel electrodes PXE may be connected to each pixel circuit PXC. The pixel electrodes PXE may be individually provided in each light emitting area EA and electrically connected to the light emitting elements LE located in each light emitting area EA. Accordingly, the light emitting elements LE disposed in each light emitting area EA may be individually and/or independently controlled.

Each of the pixel electrodes PXE may be disposed on the corresponding pixel circuit PXC. In an embodiment, each of the pixel electrodes PXE may be integral with the pixel circuit PXC and may be an electrode exposed from the pixel circuit PXC. For example, each of the pixel electrodes PXE may protrude from a top surface of the pixel circuit PXC. Each of the pixel electrodes PXE may receive a pixel voltage from the pixel circuit PXC. The pixel electrodes PXE may include a conductive material (e.g., a metal material such as aluminum (Al)).

In an embodiment, the first insulating layer INS1 may be disposed around the pixel electrodes PXE. The first insulating layer INS1 may be provided on a top surface of the semiconductor circuit board on which the pixel circuits PXC are formed. In an embodiment, the first insulating layer INS1 may be disposed between the pixel electrodes PXE to surround the pixel electrodes PXE.

The first insulating layer INS1 may expose at least a portion of each of the pixel electrodes PXE. For example, the first insulating layer INS1 may include openings corresponding to the pixel electrodes PXE and may expose the top surface of the pixel electrodes PXE. The first insulating layer INS1 may include an inorganic insulating material such as silicon oxide (SiOₓ), silicon nitride (SiNₓ), silicon oxynitride (SiOₓN_{y}), aluminum oxide (AlₓO_{y}), and aluminum nitride (AlN), or other insulating materials.

The backplane substrate 110 may further include a non-display area NDA shown in FIGS. 1 and 2. In an embodiment, the backplane substrate 110 may further include common electrode connecting portions CV, first pads PD1, and/or second pads located in the non-display area NDA.

In an embodiment, the common electrode connecting portions CVS may be disposed in the first common voltage supply area CVA1 of the non-display area NDA. The common electrode connecting portions CVS may be disposed on sides of the display area DA.

In an embodiment, the common electrode connecting portions CVS may include a first common connection electrode CCE1, a second common connection electrode CCE2, and a third common connection electrode CCE3. The first common connection electrode CCE1 and the pixel electrodes PXE may include the same material. For example, the first common connection electrode CCE1 and the pixel electrode PXE may be formed through the same process. The first common connection electrode CCE1 and the pixel electrode PXE may be formed to have the same thickness in the third direction DR3.

The second common connection electrode CCE2 may be disposed on the first common connection electrode CCE1. The second common connection electrode CCE2 and bonding electrodes BOE may include the same material. For example, the second common connection electrode CCE2 and the bonding electrodes BOE may be formed through the same process. However, the second common connection electrode CCE2 may have a lower thickness in the third direction DR3 than the bonding electrodes BOE.

The third common connection electrode CCE3 may be disposed on the second common connection electrode CCE2 and may serve to transmit a common voltage signal of the light emitting elements LE from the second common connection electrode CCE2. The third common connection electrode CCE3 and the bonding electrodes BOE may be formed of the same material, but the third common connection electrode CCE3 is not limited thereto. The third common connection electrode CCE3 may be thick in the third direction DR3 to connect the second common connection electrode CCE2 and the light emitting elements LE.

Each of the first pads PD1 may be connected to a pad electrode CPD of the circuit board CB through a conductive connection member such as a corresponding wire WR. For example, the first pads PD1, the wires WR, and the pad electrodes CPD of the circuit board CB may be connected to each other in a one-to-one correspondence.

In an embodiment, the first pad PD1 may include a first pad electrode PDE1 and a second pad electrode PDE2. The first pad electrode PDE1 and the first common connection electrode CCE1 may include the same material. For example, the first pad electrode PDE1 and the first common connection electrode CCE1 may be formed through the same process. The first pad electrode PDE1 and the first common connection electrode CCE1 may have the same thickness in the third direction DR3.

The second pad electrode PDE2 may be disposed on the first pad electrode PDE1. The second pad electrode PDE2 and the second common connection electrode CCE2 may include the same material. For example, the second pad electrode PDE2, the second common connection electrode CCE2, and the bonding electrodes BOE may be formed through the same process. The second pad electrode PDE2 and the second common connection electrode CCE2 may be formed to have the same thickness in the third direction DR3. However, the thickness of the second pad electrode PDE2 in the third direction DR3 may be lower than that of the bonding electrodes BOE.

The circuit board CB may be a flexible printed circuit board (FPCB), a printed circuit board (PCB), a flexible printed circuit (FPC), or a flexible film such as a chip-on-film (COF).

The light emitting element layer 120 may include bonding electrodes BOE, light emitting elements LE, and a common electrode CE. In an embodiment, the light emitting element layer 120 may further include an organic layer ORL disposed around the light emitting elements LE, and/or a second insulating layer INS2 disposed on the common electrode CE.

In an embodiment, the light emitting element layer 120 may further include additional components. For example, the light emitting element layer 120 may further include a reflective layer and/or a light blocking layer provided between the light emitting elements LE and/or on the sides of the light emitting elements LE.

The bonding electrodes BOE may be provided at positions corresponding to each pixel electrode PXE and may be electrically connected to each pixel electrode PXE. For example, the bonding electrodes BOE may be disposed on each pixel electrode PXE. The bonding electrodes BOE may be individually patterned in a shape corresponding to each pixel electrode PXE. For example, the bonding electrodes BOE may be patterned to have a size and/or a shape corresponding to each of the pixel electrodes PXE and may be separated from each other.

The bonding electrodes BOE may include a first bonding electrode and a second bonding electrode. The second bonding electrode may be disposed on the first bonding electrode, and the first bonding electrode and the second bonding electrode may have sizes and shapes corresponding to each other.

The first bonding electrode and the second bonding electrode may include a conductive bonding material suitable for bonding or applying the light emitting elements LE to the pixel electrodes PXE. For example, each of the second bonding electrodes BOE2 may be a single-layer or multi-layer electrode including gold (Au), copper (Cu), aluminum (Al), tin (Sn), or other metallic material (e.g., bonding metal).

The light emitting elements LE may be disposed on each bonding electrode BOE. The light emitting elements LE may be electrically connected between each pixel electrode PXE and the common electrode CE.

The light emitting elements LE may include semiconductor layers grown on a semiconductor substrate (e.g., a wafer substrate) by epitaxial growth. For example, the light emitting elements LE may include a first semiconductor layer doped with a first conductivity type dopant, a second semiconductor layer doped with a second conductivity type dopant, and an active layer interposed between the first and second semiconductor layers.

The light emitting elements LE may be formed as an epitaxial thin film of wafer dies divided from an epitaxial wafer and may be patterned in a cell area corresponding to each display panel 100 to be formed in each light emitting area EA. A detailed description of the structure and manufacturing method of the light emitting elements LE according to embodiments will be described below.

The organic layer ORL may be provided around the light emitting elements LE. In an example, the organic layer ORL may be disposed between the light emitting areas EA to surround the light emitting areas EA provided with the light emitting elements LE and may surround the light emitting elements LE and the second bonding electrodes BOE2. In an embodiment, the organic layer ORL may be a filler that fills the gap between the light emitting elements LE. The organic layer ORL may expose a portion of the light emitting elements LE, for example, the top surface.

The organic layer ORL may include an insulating material. For example, the organic layer ORL may be a single layer or multiple layers of an organic insulating film including an acrylic resin, epoxy resin, phenolic resin, polyamide resin, polyimide resin, or other organic insulating materials.

The common electrode CE may be disposed on top of the light emitting elements LE that are not covered by the organic layer ORL. In an embodiment, the common electrode CE may be entirely disposed in the display area DA to cover the light emitting elements LE and the organic layer ORL. The common electrode CE may be a common layer commonly formed and/or connected to the light emitting elements LE and the pixels PX including them in the display area DA.

The common electrode CE may be electrically connected to the common electrode connecting portions CVS disposed in the first common voltage supply area CVA1 and/or the second common voltage supply area CVA2 of FIGS. 1 and 2. Accordingly, the common electrode CE may be supplied with the common voltage through the common electrode connecting portions CVS.

The common electrode CE may include a transparent conductive material capable of transmitting light. For example, the common electrode CE may be made of indium tin oxide (ITO), indium zinc oxide (IZO), or other transparent conductive materials. In an embodiment, it may function as a cathode electrode (or anode electrode) of the light emitting elements LE.

The second insulating layer INS2 may be disposed on the common electrode CE. For example, the second insulating layer INS2 may be a capping layer disposed entirely in the display area DA to cover the common electrode CE. The second insulating layer INS2 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), or other insulating materials.

In an embodiment, the display panel 100 may include a lens-type optical structure LS provided on the light emitting element layer 120. The display panel 100 may further include a protective layer PRL covering the lens-type optical structure LS.

The lens-type optical structure LS may be disposed in each light emitting area EA to overlap the light emitting elements LE. In an embodiment, the lens-type optical structure LS may be an optical structure in the form of a convex lens provided on top of the light emitting elements LE, but the type and/or shape of the optical structure is not limited thereto. By disposing the lens-type optical structure LS on top of the light emitting elements LE, the light output characteristics of the pixels PX may be adjusted and/or improved.

The lens-type optical structure LS may be formed of a transparent material to allow light incident from the light emitting elements LE to be transmitted. For example, the lens-type optical structure LS may be formed of glass, plastic, ceramic, or other materials, and may be formed of an optical material with a high refractive index.

The protective layer PRL may be disposed on the lens-type optical structure LS to cover the lens-type optical structure LS. The protective layer PRL may be formed of a transparent and durable material (e.g., plastic or organic glass, optical glass, ceramic, etc.), but is not limited thereto as long as the material is suitable for protecting the lens-type optical structure LS. Although FIG. 3 illustrates an embodiment in which the protective layer PRL has a curve corresponding to the shape of the lens-type optical structure LS, the embodiments are not limited thereto. For example, the protective layer PRL may be formed in a shape that may planarize the top surface of the display panel 100 on which the lens-type optical structure LS is formed.

FIG. 4 is a schematic cross-sectional view illustrating a light emitting element according to an embodiment.

Referring to FIG. 4, the light emitting element LE may include a first semiconductor layer SEM1, an active layer MQW, and a second semiconductor layer SEM2 sequentially arranged and/or stacked each other in the third direction DR3. In an embodiment, the light emitting element LE may further include a contact electrode CTE provided at one end thereof. For example, the light emitting element LE may further include a contact electrode CTE provided at one end thereof where the first semiconductor layer SEM1 is located.

The light emitting element LE may further include additional layers depending on embodiments. For example, the light emitting element LE may further include an electron blocking layer disposed between the first semiconductor layer SEM1 and the active layer MQW, and/or a superlattice layer disposed between the active layer MQW and the second semiconductor layer SEM2.

In an embodiment, the light emitting element LE may be an inorganic light emitting element made of an inorganic material. For example, the light emitting element LE may be an inorganic light emitting diode formed of a nitride-based semiconductor material such as GaN, AlGaN, InGaN, AlInGaN, AlN, or InN, a phosphide-based semiconductor material such as GaP, GaInP, AlGaP, AlGaInP, AlP, or InP, or any other inorganic materials.

The contact electrode CTE may be provided and/or formed at one end of the light emitting element LE where the first semiconductor layer SEM1 is disposed. For example, the contact electrode CTE may be provided and/or formed on one surface of the first semiconductor layer SEM1. The contact electrode CTE may be an electrode that protects the first semiconductor layer SEM1 and smoothly connects the first semiconductor layer SEM1 to at least one circuit element, electrode, wiring, and/or conductive layer. The contact electrode CTE may include a metal, metal oxide, or other conductive materials.

The first semiconductor layer SEM1 may be disposed on the contact electrode CTE. In an embodiment, the first semiconductor layer SEM1 may include a nitride-based semiconductor material or a phosphide-based semiconductor material. For example, the first semiconductor layer SEM1 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The first semiconductor layer SEM1 may include other materials.

The first semiconductor layer SEM1 may include a semiconductor material doped with a first conductivity type dopant. For example, the first semiconductor layer SEM1 may include GaN (e.g., p-GaN) doped with a first conductive dopant (e.g., p-type dopant) such as Mg, Zn, Ca, Se, Ba, or the like.

The active layer MQW may be disposed on the first semiconductor layer SEM1. The active layer MQW may emit light by recombination of electron-hole pairs according to an electrical signal applied through the first semiconductor layer SEM1 and the second semiconductor layer SEM2. For example, the active layer MQW may be a light emitting layer of the light emitting element LE.

The active layer MQW may include a material with a single or multiple quantum well structure. In case that the active layer MQW includes a material with a multiple quantum well structure, the active layer MQW may have a structure in which well layers and barrier layers are alternately stacked each other. The active layer MQW may include three to five different semiconductor materials, depending on the wavelength band of the light emitted.

In an embodiment, the active layer MQW may include a nitride-based semiconductor material or a phosphide-based semiconductor material. For example, the active layer MQW may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP, and InP. For example, the well layer may be formed of InGaN, and the barrier layer may be formed of GaN or AlGaN, but embodiments are not limited thereto. In case that the active layer MQW includes InGaN, the color of light emitted from the light emitting element LE may be controlled by adjusting the content of indium (In). The active layer MQW may also include other materials.

In an embodiment, the active layers MQW of the first light emitting element LE1, the second light emitting element LE2, and the third light emitting element LE3 shown in FIGS. 2 and 3 may emit light of the same color (e.g., blue light) as each other. In another embodiment, the active layers MQW of the first light emitting element LE1, the second light emitting element LE2, and the third light emitting element LE3 may emit different colors of light (e.g., red light, green light, and blue light, respectively).

The second semiconductor layer SEM2 may be disposed on the active layer MQW. In an embodiment, the second semiconductor layer SEM2 may include a nitride-based semiconductor material or a phosphide-based semiconductor material. For example, the second semiconductor layer SEM2 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The second semiconductor layer SEM2 may also include other materials.

The second semiconductor layer SEM2 may include a semiconductor material doped with a second conductivity type dopant. For example, the second semiconductor layer SEM2 may include GaN (e.g., n-GaN) doped with a second conductive dopant (e.g., n-type dopant), such as Si, Ge, Sn, or the like.

In an embodiment, the first semiconductor layer SEM1 and the second semiconductor layer SEM2 may have different thicknesses in a thickness direction of the light emitting element LE (e.g., the third direction DR3). For example, the second semiconductor layer SEM2 may have a larger thickness than the first semiconductor layer SEM1 in the thickness direction of the light emitting element LE. Accordingly, the active layer MQW may be located closer to a first end (for example, a p-type end) of the light emitting element LE provided with the first semiconductor layer SEM1 than to a second end (for example, an n-type end) of the light emitting element LE provided with the second semiconductor layer SEM2.

In an embodiment, the light emitting element LE may be a vertical micro-LED extending and/or stacked in the third direction DR3. For example, the light emitting element LE may be a micro-LED having a length in the first direction DR1, a length in the second direction DR2, and a length in the third direction DR3 of tens to hundreds of micrometers (μm), respectively. In an embodiment, the length of the light emitting element LE in the first direction DR1, the length in the second direction DR2, and the length in the third direction DR3 may each be about 100 μm or less.

In an embodiment, the light emitting element LE may include a substantially vertical side surface as shown in FIG. 4. For example, the light emitting element LE may be patterned through vertical etching and may have a rectangular or square cross-sectional shape where the width of the top surface and the width of the bottom surface are substantially equal.

The shape of the light emitting element LE may be varied depending on embodiments. For example, the light emitting element LE may have a cross-sectional shape in which the width of the top surface and the width of the bottom surface are different, but is not limited to this. For example, the light emitting element LE may have an inverted tapered cross-sectional shape. For example, the light emitting element LE may have an inverted trapezoidal cross-sectional shape in which the width of the top surface is greater than the width of the bottom surface.

In an embodiment, the light emitting element LE may be disposed on the backplane substrate 110 such that the first semiconductor layer SEM1 is located below the active layer MQW and the second semiconductor layer SEM2 is located above the active layer MQW, as shown in FIG. 4. For example, the light emitting element LE may be disposed in each light emitting areas EA such that the contact electrode CTE (or first semiconductor layer SEM1) contacts the second bonding electrode BOE2 in FIG. 3 and the second semiconductor layer SEM2 (or other contact electrodes provided on the second semiconductor layer SEM2) contacts the common electrode CE. In this case, the common electrode CE may be a cathode electrode.

The structure, material, size, and/or shape of the light emitting element LE are not limited to the above-described embodiments. For example, the structure, material, size, and/or shape of the light emitting element LE may be varied depending on embodiments.

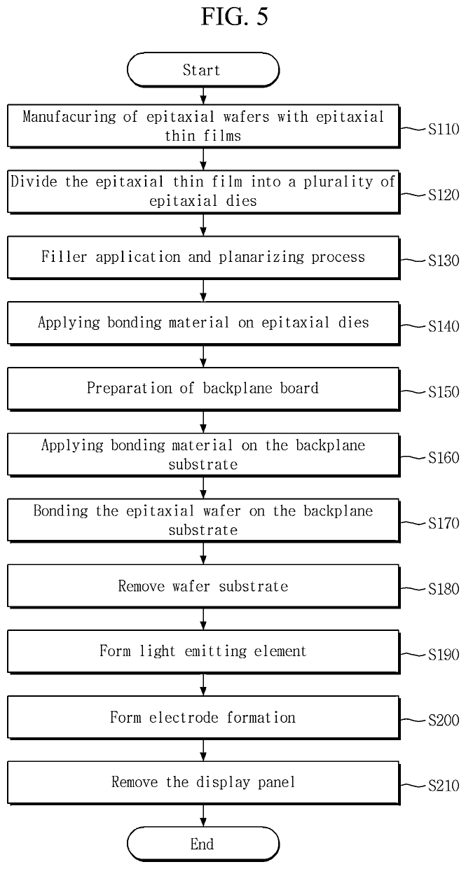

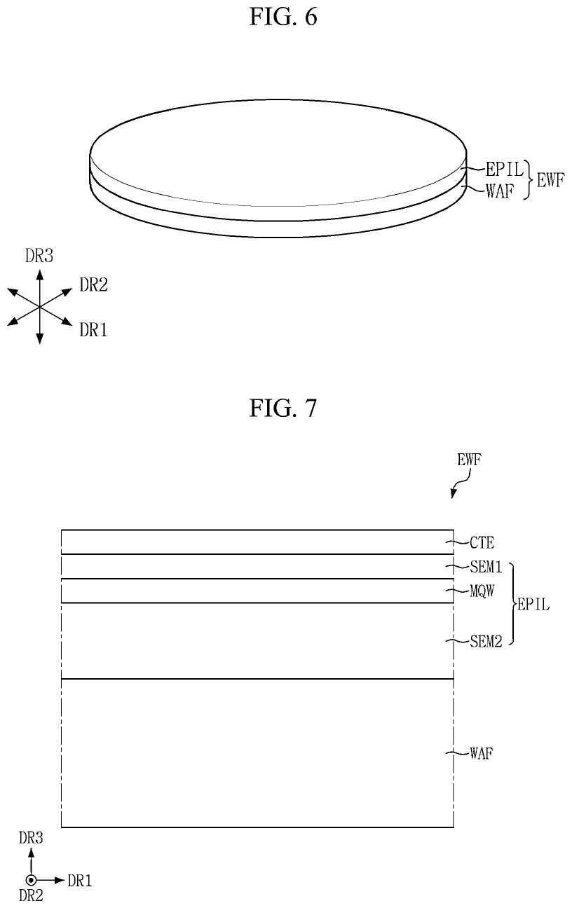

FIG. 5 is a schematic flowchart illustrating a manufacturing method of a display device according to an embodiment. For example, FIG. 5 is a schematic flowchart illustrating a method of manufacturing the display panel 100 of the display device 10 according to an embodiment. FIGS. 6 to 22 are schematic diagrams to illustrate a method of manufacturing a display panel according to an embodiment. For example, FIGS. 6 to 22 each illustrate specific steps for forming the display panel 100 in the form of a perspective view, a cross-sectional view, or a plan view.

Referring to FIGS. 6 and 7, an epitaxial wafer EWF including an epitaxial thin film EPIL may be manufactured (S110 in FIG. 5).

For example, a wafer substrate WAF (or another type of substrate suitable for epitaxial growth) may be prepared, and an epitaxial thin film EPIL may be formed on the wafer substrate WAF as shown in FIG. 6. FIG. 6 illustrates a schematic shape of an epitaxial wafer EWF in a perspective view.

The wafer substrate WAF may be a semiconductor substrate suitable for epitaxial growth of a semiconductor. For example, the wafer substrate WAF may be a substrate including a material such as silicon (Si), sapphire, SiC, GaN, GaAs, or ZnO. If the epitaxial growth for manufacturing a light emitting element LE may be performed smoothly, the type, material, and shape of the wafer substrate WAF are not limited.

As shown in FIG. 7, the epitaxial thin film EPIL may include a second semiconductor layer SEM2, an active layer MQW, and a first semiconductor layer SEM1 sequentially disposed on the wafer substrate WAF. FIG. 7 illustrates a schematic cross-sectional view of a portion of an epitaxial wafer EWF according to an embodiment.

For example, on the wafer substrate WAF, the second semiconductor layer SEM2, the active layer MQW, and the first semiconductor layer SEM1 may be sequentially formed through epitaxial growth. In an embodiment, the second semiconductor layer SEM2, the active layer MQW, and the first semiconductor layer SEM1 may be formed by epitaxial growth utilizing a process technology such as metal-organic chemical vapor deposition (MOCVD), metal-organic vapor phase epitaxy (MOVPE), molecular beam epitaxy (MBE), liquid phase epitaxy (LPE), or vapor phase epitaxy (VPE).

The second semiconductor layer SEM2 may be formed of the material of the second semiconductor layer SEM2 described above. For example, the second semiconductor layer SEM2 may be formed of at least one nitride-based semiconductor material or phosphide-based semiconductor material and may be formed as a single-layer or multi-layer semiconductor layer. The second semiconductor layer SEM2 may be doped with a second conductive type dopant (e.g., n-type dopant).

The active layer MQW may be formed of the material of the active layer MQW previously described. For example, the active layer MQW may be formed of at least one nitride-based semiconductor material or phosphide-based semiconductor material. In an embodiment, a barrier layer and a quantum well layer may be alternately and/or repeatedly formed on the second semiconductor layer SEM2 to form an active layer MQW having a multi-quantum well structure.

The first semiconductor layer SEM1 may be formed of the material of the first semiconductor layer SEM1 described above. For example, the first semiconductor layer SEM1 may be formed of a single nitride-based semiconductor material or phosphide-based semiconductor material or may be formed of a single-layer or multi-layer semiconductor layer. The first semiconductor layer SEM1 may be doped with a first conductive type dopant (e.g., a p-type dopant).

In an embodiment, when manufacturing a light emitting element LE including a contact electrode CTE as in the embodiments of FIG. 4, a process for forming the contact electrode CTE (or a conductive layer for forming the contact electrode CTE) on the epitaxial thin film EPIL may be further performed. For example, the epitaxial wafer EWF may further include the contact electrode CTE formed on the second semiconductor layer SEM2 as shown in FIG. 7.

The contact electrode CTE may be formed of the material of the contact electrode CTE previously described. The contact electrode CTE may be formed through a process such as applying (e.g., depositing) a conductive material on the epitaxial thin film EPIL, and the method of forming the contact electrode CTE is not limited.

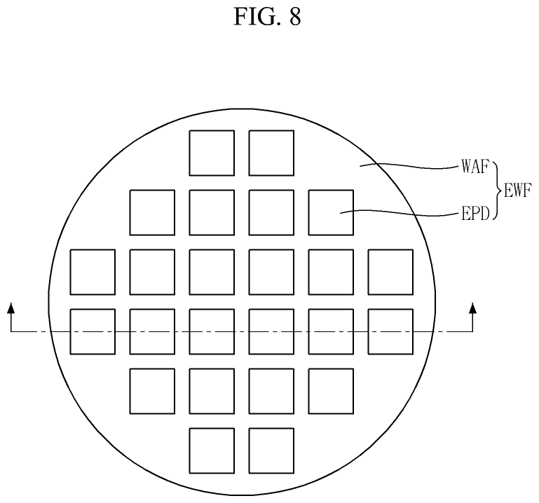

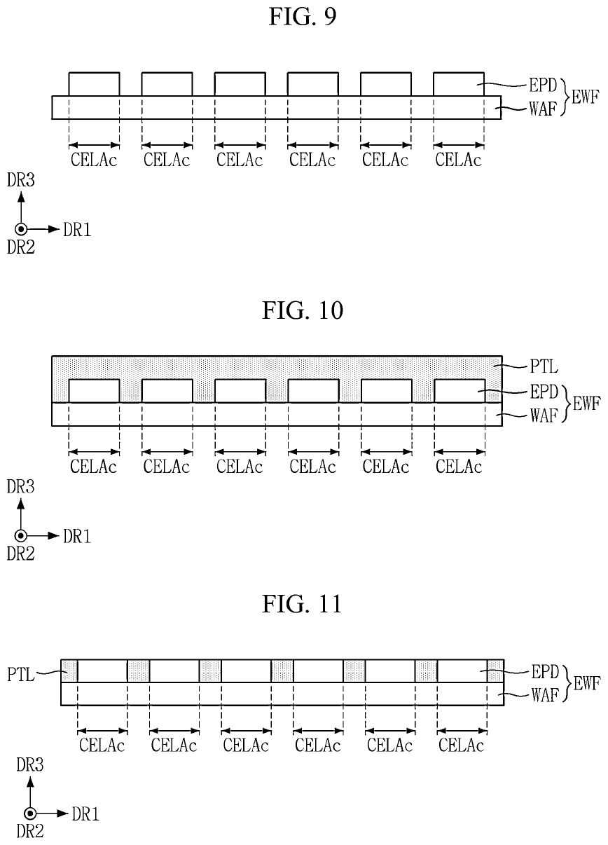

Referring to FIGS. 8 and 9, an epitaxial thin film EPIL may be divided into epitaxial dies EPD (S120 of FIG. 5). As an example, the epitaxial thin film EPIL may be diced to produce the divided epitaxial dies EPD on the wafer substrate WAF. FIG. 8 is a schematic plan view illustrating the schematic shape of an epitaxial wafer EWF including epitaxial dies EPD divided on a wafer substrate WAF, and FIG. 9 is a schematic cross-sectional view illustrating an embodiment of a cross-section of the epitaxial wafer corresponding to line X1-X1′ in FIG. 8.

The cross-sectional structure of each of the epitaxial dies EPD may be substantially the same as that of the epitaxial thin film EPIL. For example, each of the dies EPD may include an epitaxial thin film EPIL divided into smaller sizes.

Each of the epitaxial dies EPD may or may not include a contact electrode CTE depending on the embodiment. For convenience, the illustration of the contact electrode CTE will be omitted in FIGS. 6 to 22.

In an embodiment, each of the epitaxial dies EPD may have a size (e.g., an area corresponding to an area of each cell area) of a backplane substrate (e.g., a backplane substrate plate to be divided into backplane substrates 110 of each display panel 100) including cell areas for forming the display panels 100. For example, by dividing the epitaxial thin film EPIL into a size corresponding to the area of each cell area CELAc of a backplane substrate including cell areas, the epitaxial dies EPD of a size corresponding to the area of each cell area CELAc may be manufactured. A cell may be divided into an active area corresponding to the display area DA and a pad area corresponding to the non-display area NDA. The pad area may be placed around the active area or may surround the active area. In an embodiment, each of the epitaxial dies EPD may have a size greater than or equal to the area of the display area DA (or active area) located in each cell area CELAc. In an embodiment, each of the epitaxial dies EPD may have a size that is less than or equal to the area of the panel area.

In an embodiment, the epitaxial dies EPD may be disposed a certain distance away from the edge of the wafer substrate WAF.

Referring to FIGS. 10 and 11, through a filler application and planarization process, a protective layer PTL (referred to as a die protective layer PTL to distinguish it from a protective layer PRL disposed on a lens-type optical structure LS) may be formed (S130 of FIG. 5).

For example, a filler may be applied on the wafer substrate WAF on which the epitaxial dies EPD are provided to fill the gap between the epitaxial dies EPD, and to planarize the top surface of the wafer substrate WAF on which the epitaxial dies EPDs and the filler are provided. For example, an inorganic insulating material, such as silicon oxide (SiOₓ), silicon nitride (SiNₓ), silicon oxynitride (SiOₓN_{y}), aluminum oxide (AlₓO_{y}), aluminum nitride (AlN), or the like, or other insulating materials may be applied (e.g., deposited) on the top surface of the wafer substrate WAF to cover the epitaxial dies EPD.

In an embodiment, the planarization process may be performed by a polishing process such as a chemical mechanical polishing (CMP) process, but the method of planarizing the top surface of the wafer substrate WAF is not limited thereto. For example, the top surface of the wafer substrate WAF may be planarized by an etching process or the like.

In the process of planarizing the top surface of the wafer substrate WAF, the epitaxial dies EPD may be exposed. For example, a planarization process may be performed on a wafer substrate WAF provided with epitaxial dies EPD to expose the top surface of the epitaxial dies EPD. The filler may remain on a side of the wafer substrate WAF to fill the gap between the epitaxial dies EPD. Sides of the epitaxial dies EPD may be surrounded by the filler. Therefore, the filler serves as a protective layer PTL that protects the epitaxial dies EPD.

In embodiments, the protective layer PTL may protect the side of the epitaxial die EPD before a bonding process to prevent the epitaxial die EPD from cracking, thereby preventing or minimizing problems such as a failure in the epitaxial die EPD itself as well as equipment contamination during the process.

In embodiments, the epitaxial dies EPD may be first etched to a size corresponding to a cell area CELAc, a die protective layer PTL may be formed, and the epitaxial dies EPD may be bonded on the backplane substrate. After that, each epitaxial die EPD may be patterned into finer-sized light emitting elements LE through an etching process.

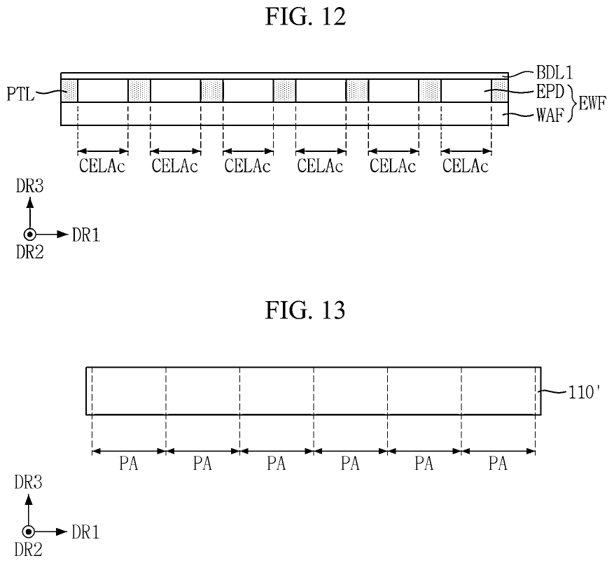

Referring to FIG. 12, a bonding material may be applied on epitaxial dies EPD (S140 in FIG. 5).

For example, a first conductive bonding layer BDL1 may be formed on the epitaxial die and the protective layer PTL by applying a conductive bonding material entirely on the top surface of the wafer substrate WAF where the epitaxial die EPD is exposed. For example, the first conductive bonding layer BDL1 may be formed by entirely applying (e.g., depositing) gold (Au), copper (Cu), aluminum (Al), tin (Sn), or other bonding metals on the top surface of the wafer substrate WAF.

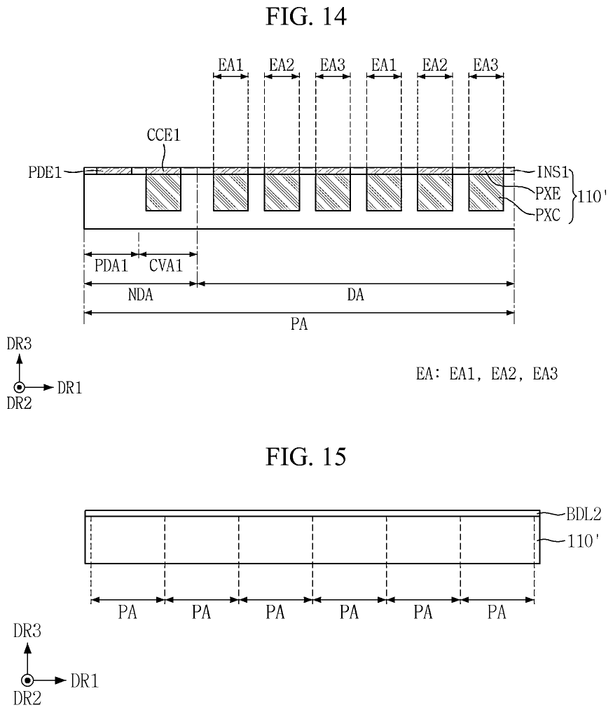

Referring to FIGS. 13 and 14, a backplane substrate 110′ including panel areas PA may be prepared (S150 in FIG. 7). FIG. 13 is a schematic cross-sectional view illustrating a schematic shape of the backplane substrate 110′, and FIG. 14 is a schematic cross-sectional view illustrating each panel area PA of the backplane substrate 110′.

Each of the panel areas PA of the backplane substrate 110′ may include a non-display area NDA and a display area DA, and each of the display areas DA may include light emitting areas EA where the light emitting elements LE are formed. The backplane substrate 110′ may include pixel electrodes PXE provided in the light emitting areas EA located in each of the display areas DA. For example, the backplane substrate 110′ may include pixel electrodes PXE individually provided in the light emitting areas EA of each panel area PA, pixel circuits PXC connected to each of the pixel electrodes PXE, and a first insulating layer INS1 disposed around the periphery of the pixel electrodes (PXEs). Further, the non-display area NDA of the backplane substrate 110′ may include a first pad electrode PDE1 and a first common connection electrode CCE1, and a first insulating layer INS1 disposed around the first pad PD1 and the first common connection electrode CCE1. In an embodiment, the first pad electrode PDE1 and the first common connection electrode CCE1 of the non-display area NDA and the pixel electrodes PXE of the display area DA may be disposed on the same plane.

The panel areas PA of the backplane substrate 110′ may be divided into backplane substrates 110 of the display panels 100 below.

The step of preparing the backplane substrate 110′ may be performed independently of the step of preparing the wafer substrate WAF to form the epitaxial dies EPD. For example, the step of preparing the backplane substrate 110′ may be performed simultaneously with the step of forming the epitaxial thin film EPIL or may be performed before or after the step of preparing the epitaxial thin film EPIL.

Referring to FIG. 15, a bonding material may be applied on the backplane substrate 110′ (S160 in FIG. 5).

For example, a second conductive bonding layer BDL2 may be formed on the panel area PA by entirely applying a conductive bonding material on the top surface of the backplane substrate 110′. The method of forming the second conductive bonding layer BDL2 may be the same as the method of forming the first conductive bonding layer BDL1.

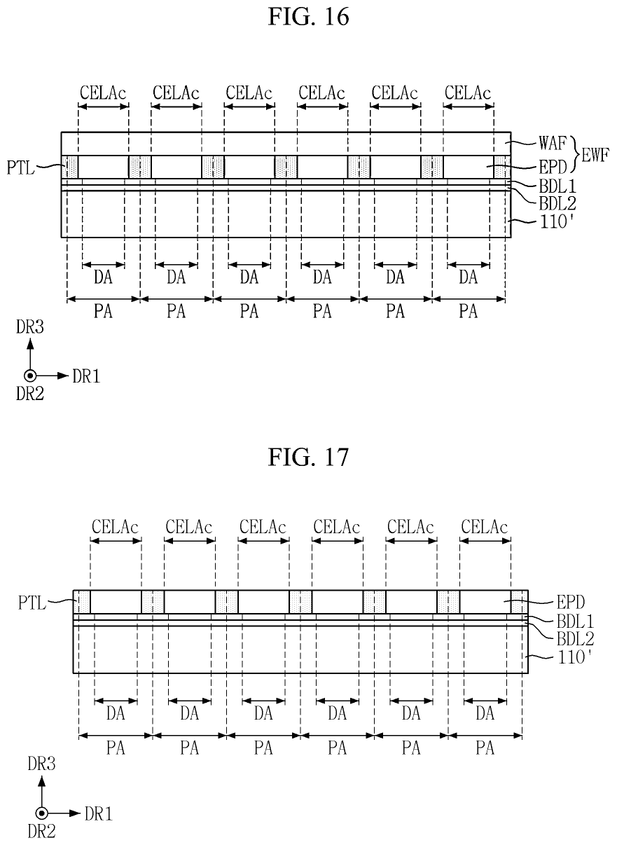

Referring to FIG. 16, an epitaxial wafer EWF may be bonded to the backplane substrate 110′ (S170 in FIG. 5).

For example, a wafer substrate WAF may be placed on the backplane substrate 110′ by aligning the epitaxial dies EPD to be positioned in each panel area PA of the backplane substrate 110′, and the epitaxial wafer EWF and the backplane substrate 110′ may be bonded using a first conductive bonding layer BDL1 and a second conductive bonding layer BDL2. Accordingly, the epitaxial dies EPD may be bonded to each panel area PA of the backplane substrate 110′. The epitaxial dies EPD may be bonded to be positioned on the pixel electrodes PXE located in the light emitting areas EA of each panel area PA.

In an embodiment, an align key may be disposed on the backplane substrate 110′ and the wafer substrate WAF, respectively. Accordingly, the backplane substrate 110′ and the wafer substrate WAF may be readily and/or appropriately aligned and bonded. For example, the epitaxial dies EPD of the wafer substrate WAF may be aligned with the display areas DA defined in the panel areas PA of the backplane substrate 110′ and be bonded to the backplane substrate 110′.

The cell area CELA may be disposed within the corresponding panel area PA and may include the display area DA. The cell area CELA may be smaller than the corresponding panel area PA area and greater than the corresponding display area DA.

In an embodiment, the first conductive bonding layer BDL1 of the backplane substrate 110′ and the second conductive bonding layer BDL2 of the wafer substrate WAF may be bonded by melting the first conductive bonding layer BDL1 of the backplane substrate 110′ and the second conductive bonding layer BDL2 of the wafer substrate WAF through a thermal compression (TC) bonding. The first conductive bonding layer BDL1 and the second conductive bonding layer BDL2 may be melt-bonded at a temperature (e.g., a predetermined or selectable predetermined temperature) to form a single conductive bonding layer BDL. For example, the conductive bonding layer BDL may be disposed between the backplane substrate 110′ and the wafer substrate WAF to serve as a bonding metal layer to bond the backplane substrate 110′ and the wafer substrate WAF.

The bonding (or adhesion) method of the backplane substrate 110′ and the wafer substrate WAF is not limited to this, and the backplane substrate 110′ and the wafer substrate WAF may be bonded by other methods.

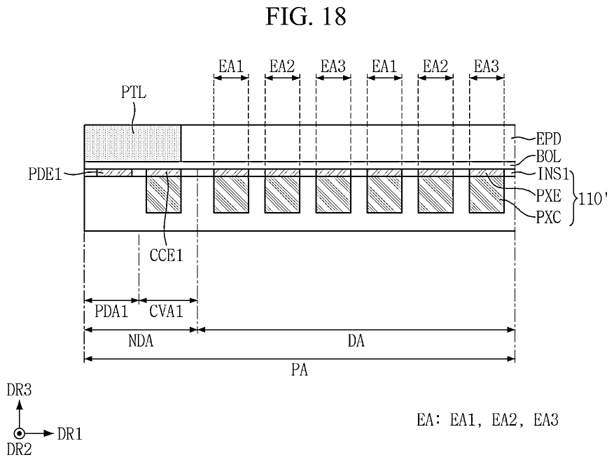

Referring to FIGS. 17 and 18, the wafer substrate WAF may be removed from the epitaxial dies EPD (S180 in FIG. 5).

For example, the wafer substrate WAF may be removed from the epitaxial dies EPD bonded to the bonding layer BDL of the backplane substrate 110′. In an embodiment, the wafer substrate WAF may be readily and/or appropriately removed from the epitaxial dies EPD through a polishing process such as a chemical mechanical polishing (CMP) process and/or an etching process. The top of the epitaxial dies EPD may be exposed by removing the wafer substrate WAF.

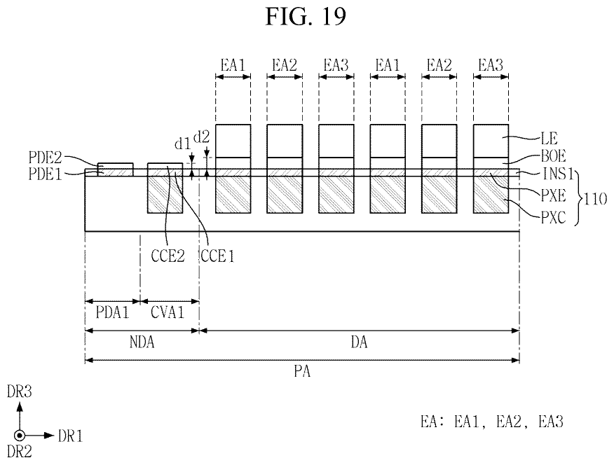

Referring to FIG. 19, light emitting elements LE, bonding electrodes BOE, and second common connection electrode CCE2 may be formed (S190 in FIG. 5).

For example, the epitaxial dies EPD may be etched to form each light emitting element LE in the light emitting area EA included in each cell area CELA. The light emitting elements LE may be formed on pixel electrodes PXE located in each light emitting area EA.

A conductive bonding layer BDL may be etched to form bonding electrodes BOE between the pixel electrodes PXE and the light emitting elements LE. In an embodiment, the light emitting elements LE and the bonding electrodes BOE may be formed in a size and/or shape corresponding to the pixel electrodes PXE and/or the bonding electrodes BOE. For example, the light emitting elements LE and the bonding electrodes BOE may be formed to have an area corresponding to the area of the pixel electrodes PXE and to have a planar shape that follows the planar shape of the pixel electrodes PXE. However, the embodiments are not limited to this, and the size and shape of the light emitting elements LE and the bonding electrodes BOE may be varied depending on embodiments.

Furthermore, during an etching process to form the light emitting elements LE by etching the epitaxial dies EPD, a die protective layer PTL may be etched. Since the die protective layer PTL is etched faster than the semiconductor layers of the epitaxial dies EPD, the conductive bonding layer BDL below the die protective layer PTL may be further etched after the die protective layer PTL has been etched. This may be due to the different etch rate between the epitaxial thin film and the protective layer PTL. Therefore, the second common connection electrode CCE2 and the second pad electrode PDE2 formed by etching the conductive bonding layer BDL of the non-display area NDA may have a thickness d1 in the third direction smaller than the thickness d2 of the bonding electrodes BOE of the display area DA in the third direction.

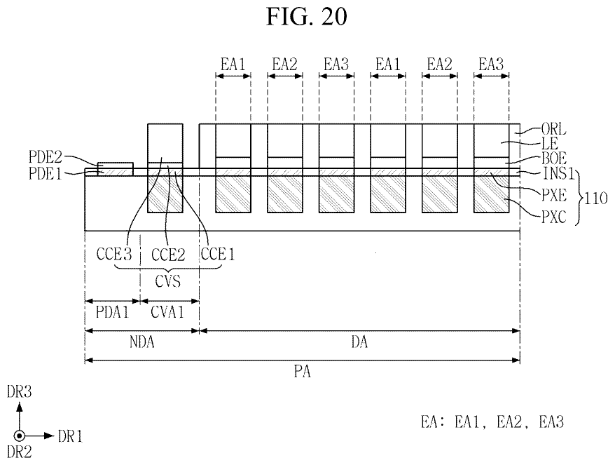

Referring to FIGS. 20 to 22, subsequent processes to form the light emitting element layer 120 may be performed, including a process for forming the common electrode CE (S200 in FIG. 5).

For example, an organic layer ORL may be formed between the light emitting elements LE in each cell area CELA as shown in FIG. 20. In an example, the organic layer ORL may be filled between the light emitting elements LE at least in the display area DA.

A third common connection electrode CCE3 may be formed on the second common connection electrode CCE2 using a conductive material.

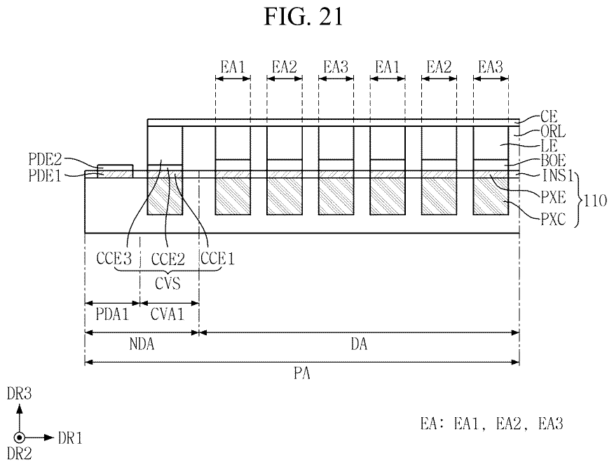

A common electrode CE may be formed on the light emitting elements LE in each cell area CELA as shown in FIG. 21.

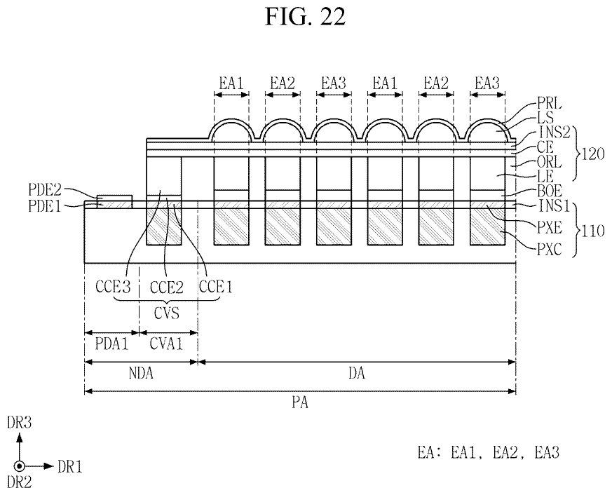

Thereafter, a second insulating layer INS2 may be formed on the common electrode CE as shown in FIG. 22.

In an embodiment, when manufacturing the display panel 100 including a light conversion layer and/or a color filter layer, the process of forming the light conversion layer and/or the color filter layer on top of the light emitting element layer 120 or inside the light emitting element layer 120 may be further carried out.

In an embodiment, when manufacturing the display panel 100 including the lens-type optical structure LS as shown in FIG. 3, the process of attaching and/or forming the lens-type optical structure LS and the protective layer PRL, etc. on the light emitting element layer 120 may further proceed.

After the actual manufacturing process of the display panels 100 is completed, a process of separating each display panel may be performed (S210 in FIG. 5).

For example, the display panels 100 formed based on a backplane substrate 110′ may be individually separated through display panel separation. For example, by cutting the backplane substrate 110′ based on the display areas PA, each cell located in the cell areas CELA may be separated into individual display panels 100.

Thereafter, the display device 10 including each display panel 100 may be manufactured by further proceeding with a modular process or the like.

As described above, in embodiments, the epitaxial thin film EPIL may be divided on a cell basis (e.g., by dividing the epitaxial wafer EWF into a size greater than the area of the display area DA including the process error), and the epitaxial die EPD may be bonded to each display area CELA of the backplane substrate 110′ after forming the die protective layer PTL that protects each divided epitaxial die EPD. Afterwards, the epitaxial die EPD in each cell area CELA may be etched and patterned into individual light emitting elements LE. Accordingly, damage to the outer portion of the epitaxial thin film EPIL that may occur during bonding may be prevented. Accordingly, equipment contamination that may occur due to damage to the outer portion of the epitaxial thin film EPIL may also be prevented.

After aligning and bonding each epitaxial die EPD on each cell area CELA of the backplane substrate 110′ on a cell basis and patterning the epitaxial die EPD into light emitting elements LE, the difficulty of the panel process for manufacturing the display panel 100 may be reduced, and misalignment errors may be prevented or reduced. For example, since high-precision alignment of the finer-sized pixels PX and/or the light emitting areas EA during the bonding process becomes unnecessary, the epitaxial die EPD is bonded to the backplane substrate 110′, and the respective light emitting elements LE are formed in the light emitting areas EA by an etching process or the like, the light emitting elements LE may be readily and/or reliably formed in the proper position. Accordingly, the process efficiency of the display panel 100 and the display device 10 including the same may be increased, and the yield may be improved.

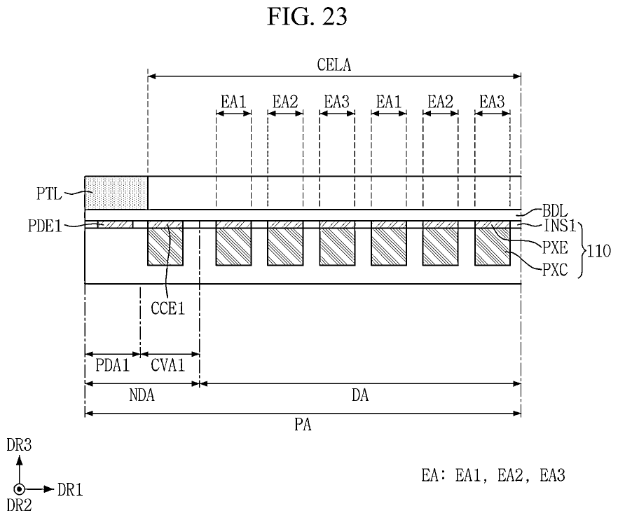

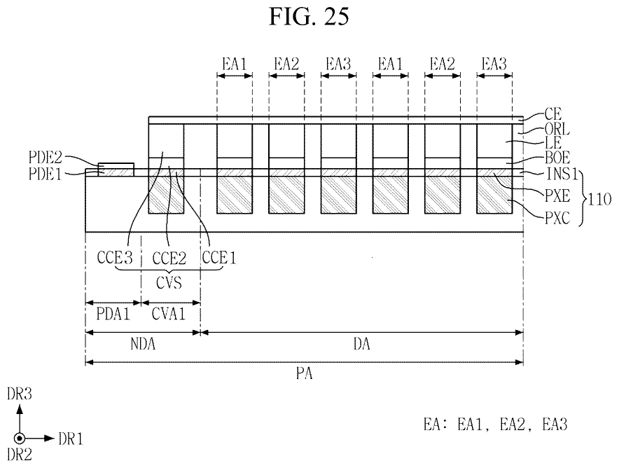

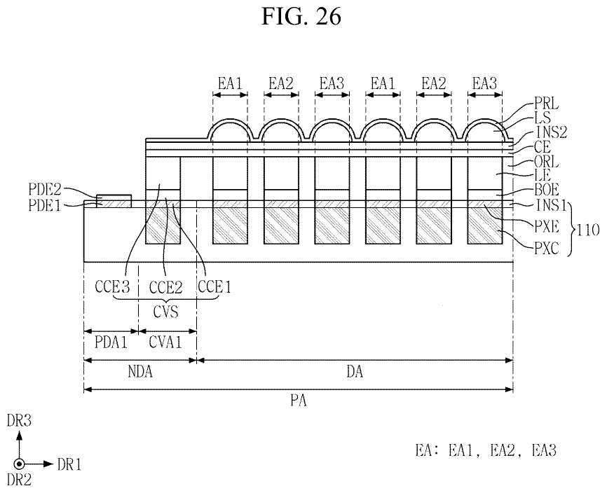

FIGS. 23 to 26 are schematic drawings to illustrate a method of manufacturing a display panel 100 according to another embodiment. For example, FIGS. 23 to 26 each illustrate specific steps for forming the display panel 100 in the form of a perspective view, a cross-sectional view, or a plan view.

The display panel described with reference to FIG. 23 may differ from the display panel described with reference to FIG. 18 in that the cell area CELA of the epitaxial dies EPD overlaps the first common voltage supply area CVA1.

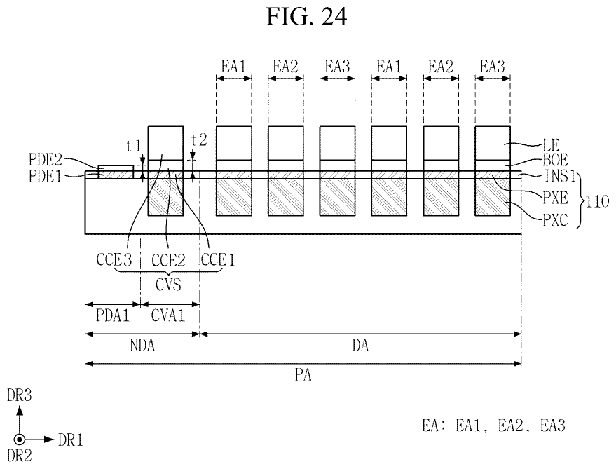

Referring to FIGS. 24 to 26, in the process of forming the light emitting elements LE, the bonding electrodes BOE, and the second common connection electrode CCE2, an epitaxial thin film EPIL overlapping the first common voltage supply area CVA1 may be etched to form a third common connection electrode CCE3. Thus, similar to the light emitting element LE, the third common connection electrode CCE3 may include semiconductor layers.

A conductive bonding layer BDL may be etched to form bonding electrodes BOE, a second common connection electrode CCE2, and a second pad electrode PDE2 between the pixel electrodes PXE and the light emitting elements LE.

Furthermore, during the etching process of etching the epitaxial dies EPD to form the light emitting elements LE, a die protective layer PTL may be etched. Since the die protective layer PTL is etched faster than the semiconductor layers of the epitaxial dies EPD, the conductive bonding layer BDL below the die protective layer PTL may be further etched after the die protective layer PTL is all etched. Therefore, the second pad electrode PDE2 formed by etching the conductive bonding layer BDL of the first pad area PDA1 may have a thickness t1 in the third direction smaller than a thickness t2 of the conductive bonding layer BOE of the display area DA and the second common connection electrode CCE2 of the first common voltage supply area CVA1 in the third direction.

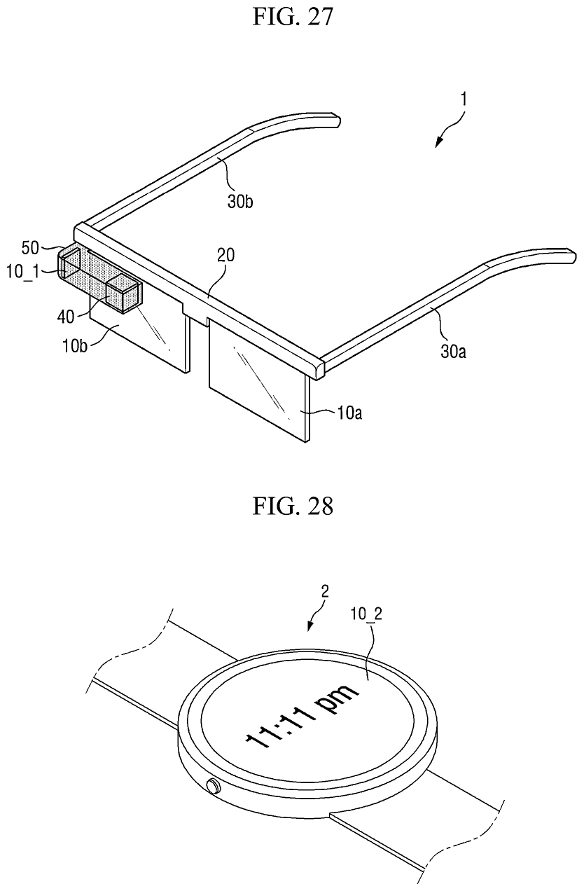

FIG. 27 is schematic example diagram illustrating a virtual reality device 1 including a display device 10_1 according to an embodiment.

Referring to FIG. 27, the virtual reality device 1 according to an embodiment may be a device in a form of glasses. The virtual reality device 1 according to an embodiment may include a display device 10_1, a left-eye lens 10a, a right-eye lens 10b, a support frame 20, left and right legs 30a and 30b, a reflective member 40, and a display device housing 50.

FIG. 27 illustrates the virtual reality device 1 including the two legs 30a and 30b. However, the disclosure is not limited thereto. The virtual reality device 1 according to an embodiment may be used in a head-mounted display including a head-mounted band that may be mounted on a head instead of the legs 30a and 30b. For example, the virtual reality device 1 according to an embodiment may not be limited to the example shown in FIG. 27, and may be applied to various electronic devices in various forms.

The display device housing 50 may receive the display device 10_1 and the reflective member 40. An image displayed on the display device 10_1 may be reflected from the reflective member 40 and provided to a user's right eye through the right-eye lens 10b. Thus, the user may view a virtual reality image displayed on the display device 10_1 via the right eye.

FIG. 27 illustrates that the display device housing 50 is disposed at a right end of the support frame 20. However, an embodiment of the disclosure is not limited thereto. For example, the display device housing 50 may be disposed at a left end of the support frame 20. The image displayed on the display device 10_1 may be reflected from the reflective member 40 and provided to the user's left eye via the left-eye lens 10a. Thus, the user may view the virtual reality image displayed on the display device 10_1 via the left eye. As another example, the display device housing 50 may be disposed at each of the left end and the right end of the support frame 20. The user may view the virtual reality image displayed on the display device 10_1 via the left eye and the right eye.

FIG. 28 is a schematic example diagram illustrating a smart device including a display device 10_2 according to an embodiment.

Referring to FIG. 28, a display device 10_2 according to an embodiment may be applied to a smart watch 2 as one of smart devices. The planar shape of a watch display part of the smart watch 2 may follow that of the display device 10_2. For example, in case that the display device 10_2 according to an embodiment has a circular or elliptical planar shape, the watch display part of the smart watch 2 may have a circular or elliptical planar shape. As another example, in case that the display device 10_2 according to an embodiment has a rectangular planar shape, the watch display part of the smart watch 2 may have a rectangular planar shape. However, embodiments are not limited thereto. The planar shape of the watch display part of the smart watch 2 may not follow that of the display device 10_2.

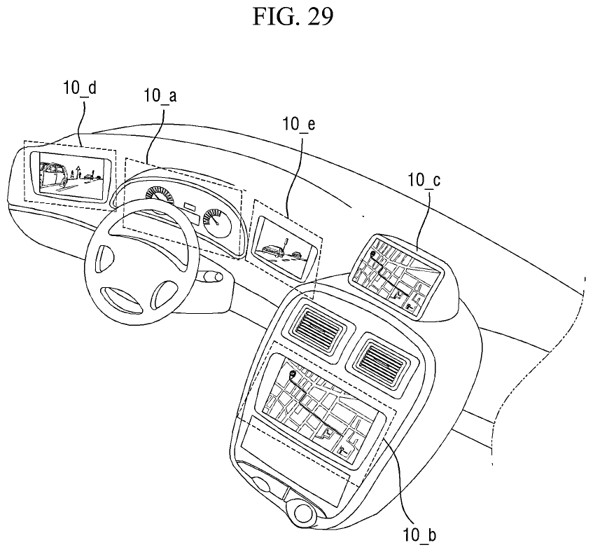

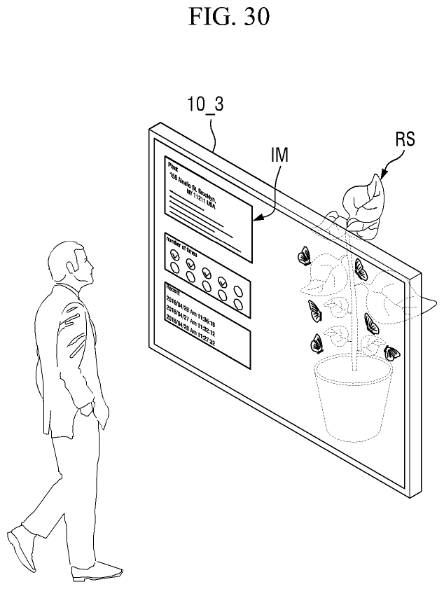

FIG. 29 is a schematic example diagram illustrating a vehicle including a display device according to an embodiment. FIG. 29 illustrates a vehicle in which display devices 10_a, 10_b, 10_c, 10_d, 10_e according to an embodiment are used.

Referring to FIG. 29, the display devices 10_a, 10_b, and 10_c according to an embodiment may be applied to the dashboard of the vehicle, applied to the center fascia of the vehicle, or applied to a CID (Center Information Display) disposed on the dashboard of the vehicle. Further, each of the display devices 10_d and 10_e according to an embodiment may be applied to a room mirror display that replaces side-view mirrors of the vehicle.

FIG. 30 is a schematic example diagram illustrating a transparent display device including a display device 10_3 according to an embodiment.

Referring to FIG. 30, the display device 10_3 according to an embodiment may be applied to a transparent display device. The transparent display device may transmit light therethrough while displaying an image IM thereon. Therefore, a user located in front of the transparent display device may not only view the image IM displayed on the display device 10_3, but also view an object RS or a background located in rear of the transparent display device. In case that the display device 10_3 is applied to the transparent display device, the display panel 100 may include a light transmitting portion that may transmit light therethrough or may be formed on a substrate member made of a material that may transmit light therethrough.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display area and a non-display area;
a substrate including a plurality of pixel electrodes disposed in the display area;
a light emitting element disposed on each of the plurality of pixel electrodes and including a first semiconductor layer, an active layer, and a second semiconductor layer;
a first common connection electrode and a second common connection electrode disposed in the non-display area; and
a bonding electrode disposed between the light emitting element and the plurality of pixel electrodes,
wherein the second common connection electrode has a thickness thinner than the bonding electrode.

2. The display device of claim 1, wherein
the second common connection electrode and the bonding electrode are disposed on a same layer, and
the first common connection electrode and the plurality of pixel electrodes are disposed on a same layer.

3. The display device of claim 2, wherein the second common connection electrode and the bonding electrode include a same material.

4. The display device of claim 2, wherein the first common connection electrode and the plurality of pixel electrodes have a same thickness.

5. The display device of claim 4, wherein the first common connection electrode and the plurality of pixel electrodes include a same material.

6. The display device of claim 1, wherein the bonding electrode has a size and shape corresponding to each of the plurality of pixel electrodes.

7. The display device of claim 6, wherein
the bonding electrode includes a first bonding electrode and a second bonding electrode disposed on the first bonding electrode, and
the second bonding electrode has a size and shape corresponding to the first bonding electrode.

8. The display device of claim 1, further comprising:
a common electrode disposed on the light emitting element and electrically connected to the second common connection electrode.

9. The display device of claim 8, further comprising:
a third common connection electrode disposed between the second common connection electrode and the common electrode.

10. The display device of claim 9, further comprising:
a lens-type optical structure disposed on a light emitting element layer including the light emitting elements and the common electrode.

11. A method of manufacturing display device comprising:
manufacturing an epitaxial wafer including an epitaxial thin film;
dividing the epitaxial thin film into epitaxial dies with a size corresponding to an area of each cell area of a backplane substrate including the cell areas;
forming a protective layer surrounding the epitaxial dies and planarizing the epitaxial dies;
forming a first conductive bonding layer on the epitaxial dies and the protective layer of the epitaxial wafer;
forming a second conductive bonding layer on a backplane substrate;
disposing a wafer substrate on the backplane substrate so that the epitaxial dies overlap each display area of the backplane substrate, and bonding the first conductive bonding layer and the second conductive bonding layer;
removing the wafer substrate from the epitaxial dies; and
etching the epitaxial dies to form each light emitting element in light emitting areas included in each cell area.

12. The method of claim 11, wherein the forming of the protective layer surrounding the epitaxial dies and planarizing the epitaxial dies includes, filling a gap between the epitaxial dies, applying a filler on the wafer substrate to cover the epitaxial dies, and planarizing a top surface of the wafer substrate to expose a top of the epitaxial dies.

13. The method of claim 11, wherein the backplane substrate includes:
pixel electrodes individually provided in light emitting areas of a display area;
a first common connection electrode in a non-display area; and
an insulating layer filling a space between the pixel electrodes and the first common connection electrode.

14. The method of claim 13, wherein the etching of the epitaxial dies to form each light emitting element in the light emitting areas included in each cell area, includes forming each of the light emitting elements on the pixel electrodes.

15. The method of claim 14, wherein the etching of the epitaxial dies to form each light emitting element in the light emitting areas included in each cell area, includes etching a bonded first conductive bonding layer and the second conductive bonding layer to form a bonding electrode between the light emitting element and the pixel electrodes and a second common connection electrode on the first common connection electrode in a same layer.

16. The method of claim 15, wherein in the etching of the epitaxial dies to form each light emitting element in the light emitting areas included in each cell area, a thickness of the second common connection electrode of a non-display area is thinner than a thickness of the bonding electrode of the display area according to a difference in etch rate between the epitaxial die and the protective layer.

17. The method of claim 15, wherein the bonding of the first conductive bonding layer and the second conductive bonding layer, includes bonding the epitaxial dies to the backplane substrate by a thermal compression (TC) bonding method.

18. The method of claim 15, further comprising:
forming a common electrode on the light emitting elements in each cell area,
wherein the common electrode is electrically connected to the second common connection electrode.

19. The method of claim 18, further comprising:
forming a lens-type optical structure on a light emitting element layer including the light emitting elements and the common electrode.

20. The method of claim 11, further comprising:
separating each cell corresponding to the cell areas into individual display panels by cutting the backplane substrate based on a panel area including the cell areas.
